(19) United States
(12) Patent Application Publication
(10) Pub. No.: US 2024/0102828 A1
(43) Pub. Date: Mar. 28, 2024

(54) DEVICE IDENTIFICATION

(71) Applicant: BRITISH TELECOMMUNICATIONS PUBLIC LIMITED COMPANY, London (GB)

(72) Inventors: Giulio GIACONI, London (GB); Fadi EL-MOUSSA, London (GB)

(21) Appl. No.: 18/255,637

(22) PCT Filed: Nov. 27, 2021
(86) PCT No.: PCT/EP2021/083258

§ 371 Date: Jun. 2, 2023

(30) Foreign Application Priority Data
Dec. 2, 2020 (GB) 2018983.3

(51) Int. Cl. G01D 4/00

(52) U.S. Cl. CPC G01D 4/004; G01D 2204/24

(57) ABSTRACT

A device identification method, a device identification system and a device prediction component. The method can include determining, based on first power consumption data indicative of a first power consumption associated with a premises within a first time period, a predicted identity of an active device at the premises within a second time period subsequent to the first time period. A detected identity of the active device at the premises within the second time period is determined, based on second power consumption data indicative of a second power consumption associated with the premises within the second time period. A determined identity of the active device at the premises within the second time period is determined, based on at least one of the predicted identity and the detected identity.

### PRIORITY CLAIM

The present application is a National Phase entry of PCT Application No. PCT/EP2021/083258, filed Nov. 27, 2021, which claims priority from GB Patent Application No. 2018983.3, filed Dec. 2, 2020, each of which is hereby fully incorporated herein by reference.

### TECHNICAL FIELD

The present disclosure relates to identification of a device.

### BACKGROUND

Appliance load monitoring (ALM) can be used to detect the operation of individual electrical devices by monitoring power outlets. There are a variety of different ALM techniques, including intrusive load monitoring (ILM) techniques, which use the power consumption measured at various measuring points within a premises, and non-intrusive load monitoring (NILM) techniques, which instead use the power consumption measured at a single point, such as at a smart meter.

### SUMMARY

It is desirable to provide improved techniques for identifying a device at a premises.

According to a first aspect of the present disclosure, there is provided a device identification method comprising determining, based on first power consumption data indicative of a first power consumption associated with a premises within a first time period, a predicted identity of an active device at the premises within a second time period subsequent to the first time period; determining, based on second power consumption data indicative of a second power consumption associated with the premises within the second time period, a detected identity of the active device at the premises within the second time period; and determining, based on at least one of the predicted identity and the detected identity, a determined identity of the active device at the premises within the second time period.

In some examples, at least one of the predicted identity, the detected identity and the determined identity indicates a version of a particular type of the active device. Determining the detected identity may comprise detecting, based on the second power consumption data, the particular type of the active device; and after detecting the particular type of the active device, detecting, based on the second power consumption data, the version of the particular type of the active device. Detecting the version of the particular type of the active device may comprise processing the second power consumption data using a hierarchical support vector machine.

In some examples, the method comprises processing the first power consumption data to generate device usage data representing an identity of at least one active device at the premises for each of at least one portion of the first time period, respectively. Determining the predicted identity may comprise processing the device usage data to determine the predicted identity. Processing the device usage data may comprise processing the device usage data using a long short-term memory (LSTM) neural network. The device usage data may represent, for each respective active device of the at least one active device, a version of a particular type of the respective active device. The method may comprise determining, based on the device usage data, whether the device usage data represents different versions of the same type of active device within different respective portions of the first time period.

In some examples, the method comprises disaggregating, from the second power consumption data, device-specific power consumption data indicative of a power consumption of the active device at the premises within the second time period, wherein determining the detected identity comprises processing the device-specific power consumption data to determine the detected identity.

In some examples, determining the determined identity of the active device comprises determining the determined identity of the active device based on at least one of: a first confidence score associated with the predicted identity and a second confidence score associated with the detected identity. Determining the determined identity of the active device may comprise determining that the determined identity of the active device corresponds to the predicted identity based on the first confidence score exceeding the second confidence score by an amount which meets or exceeds a threshold amount.

In some examples, determining the predicted identity comprises determining the predicted identity using a machine learning (ML) system, determining the determined identity of the active device comprises determining that the determined identity of the active device corresponds to the detected identity, and the method comprises retraining the ML system based on updated device usage data indicative that a device of the determined identity was active at the premises within the second time period.

In some examples, the method comprises sending an indication of the determined identity to a gateway device of a network associated with the premises, for use in determining a service to provide to the premises.

In some examples, the method comprises determining, based on at least one of the first power consumption data, the second power consumption data, the predicted identity, the detected identity or the determined identity, whether the active device corresponds to a previously-unseen device within the premises.

According to a second aspect of the present disclosure, there is provided a non-transitory computer-readable medium comprising instructions which, when executed by a computer, cause the computer to carry out the method of any example in accordance with the first aspect of the present disclosure.

According to a third aspect of the present disclosure, there is provided a device identification system comprising: a device prediction component configured to determine, based on first power consumption data indicative of a first power consumption associated with a premises within a first time period, a predicted identity of an active device at the premises within a second time period subsequent to the first time period; a device detection component configured to determine, based on second power consumption data indicative of a second power consumption associated with the premises within the second time period, a detected identity of the active device at the premises within the second time period; and a decision component configured to determine, based on at least one of the predicted identity and the detected identity, a determined identity of the active device at the premises within the second time period.

In some examples, at least one of: the predicted identity, the detected identity and the determined identity indicates a version of a particular type of the active device.

In some examples, at least one of the device prediction component, the device detection component or the decision component are further configured to process the first power consumption data to generate device usage data representing an identity of at least one active device at the premises for each of at least one portion of the first time period, respectively, and the device prediction component is configured to process the device usage data to determine the predicted identity. The device usage data may represent, for each respective active device of the at least one active device, a version of a particular type of the respective active device.

According to a fourth aspect of the present disclosure, there is provided a telecommunications network comprising the device identification system of any example in accordance with the third aspect of the present disclosure.

According to a fifth aspect of the present disclosure, there is provided a device prediction component for use in a device identification system of any example in accordance with the third aspect of the present disclosure, wherein the device prediction component is configured to: process device usage data representing an identity of at least one active device at a premises for each of a plurality of time periods to predict an identity of an active device at the premises in a subsequent time period, subsequent to the plurality of time periods.

In some examples, the device prediction component comprises a long short-term memory (LSTM) neural network to process the device usage data.

In some examples, the device usage data represents, for each respective active device of the at least one active device, a version of a particular type of the respective active device.

In some examples, the device usage data is based on power consumption data indicative of a power consumption associated with the premises within each of the plurality of time periods.

Examples in accordance with the present disclosure may include any novel aspects described and/or illustrated herein. The disclosure also extends to methods and/or apparatus substantially as herein described and/or as illustrated with reference to the accompanying drawings. Any apparatus feature may also be provided as a corresponding operation in a method, and vice versa.

The disclosure also provides a method of transmitting a signal, a computer product having an operating system that supports a computer program for performing any of the methods described herein and/or for embodying any of the apparatus features described herein, which for example may be in the form of a non-transitory computer-readable medium comprising instructions which, when executed by a computer, cause the computer to carry out any of the methods described herein and/or embody any of the apparatus features described herein.

Any feature in one aspect may be applied, in any appropriate combination, to other aspects. Any, some and/or all features in one aspect can be applied to any, some and/or all features in any other aspect, in any appropriate combination. Particular combinations of the various features described and defined in any aspects can be implemented and/or supplied and/or used independently.

As used throughout, the word ‘or’ can be interpreted in the exclusive and/or inclusive sense, unless otherwise specified.

### BRIEF DESCRIPTION OF THE DRAWINGS

For a better understanding of the present disclosure, reference will now be made by way of example only to the accompany drawings, in which:

FIG. 1 is a schematic diagram of part of a telecommunications network according to examples.

FIG. 2 is a schematic diagram of a system including a device identification system according to examples.

FIG. 3 is a schematic diagram of a device detection component according to examples.

FIG. 4 is a schematic diagram of training of a device detection component according to examples.

FIG. 5 is a schematic diagram of a device prediction component according to examples.

FIG. 6 is a schematic diagram of internal components of an example computer system for use with the methods herein.

FIG. 7 is a schematic diagram illustrating determination of anomalies using the methods herein.

### DETAILED DESCRIPTION

Apparatus and methods in accordance with the present disclosure are described herein with reference to particular examples. The disclosure is not, however, limited to such examples.

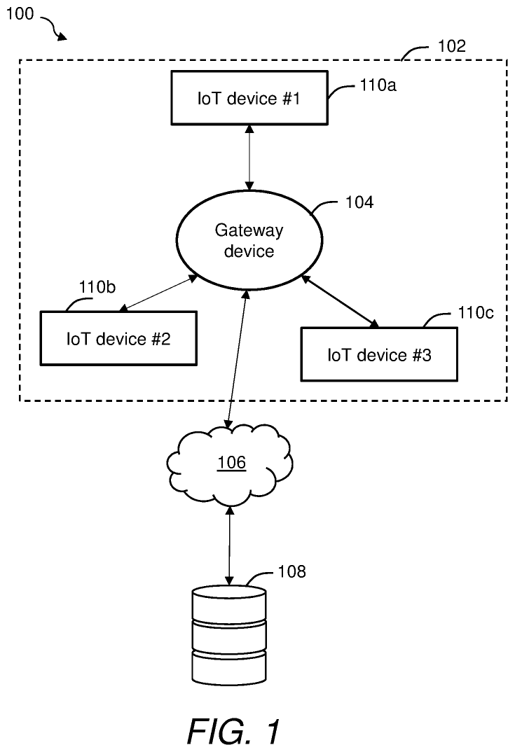

FIG. 1 is a schematic diagram of part of a telecommunications network 100, to part the examples herein into context. The telecommunications network 100 includes a local network 102, which in this case is provided by a network device. A network device is a device that provides an entry point to a telecommunications network (in this case the local network 102) or that filters and/or routes network traffic, such as a router, gateway device, switch, hub, access point or an edge device (which may be or comprise a router or routing switch). In FIG. 1, the network device is a gateway device 104, but this is merely an example. The gateway device 104 allows data to flow between the local network 102 and a wider network, for example the Internet 106, e.g. in order to facilitate communication with a remote server 108. Although only a single gateway device 104 is shown in FIG. 1, the local network 102 could employ multiple access points and/or signal boosters to perform this function.

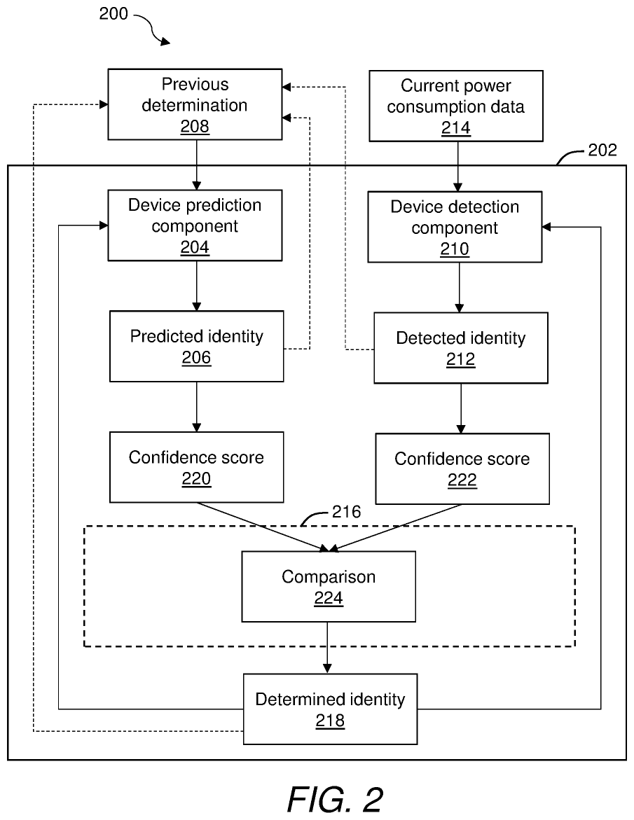

The methods described herein (discussed in detail with references to FIGS. 2 to 7) can be performed to identify a device within a premises, such as a device connected to the local network 102. In the example of FIG. 1, there are three devices 110a-110c connected to the local network 102. In this case, each of the devices is a respective IoT device, although it is to be appreciated that the methods herein may be used to identify other electrical devices than IoT devices. The IoT is a network of user devices such as home appliances and other items embedded with electronics, software, sensors, actuators, and/or connectivity which enable these devices to connect with each other and/or other computer systems and exchange data. An IoT device can for example include one or more of smart televisions (TVs), smart refrigerators, connected printers, smart lighting fixtures, smart thermostats, home security systems, smart watches, physiological or biometric sensors, and voice assistant devices.

In the telecommunications network 100 of FIG. 1, the server 108 includes a device identification system (an example of which is described further with reference to FIG. 2). Power consumption data indicative of power consumed within a premises associated with the local network 102 is sent to the server 108 for processing by the device identification system. The device identification system then identifies the nature of the devices active at the premises at a particular time (e.g. within a particular time period). For example, the device identification system can determine that a first IoT device 110a is a smart TV, which is active within a first time period, and that a second IoT device 110b is a smart lighting fixture which is also active within the first time period. A third IoT device 110c, which in this case is a voice assistant device, is not active within the first time period but is identified as being active within a second time period. It is to be appreciated that this is merely an example to illustrate the principles herein, though, and that the methods herein may be used to identify other devices active at other times.

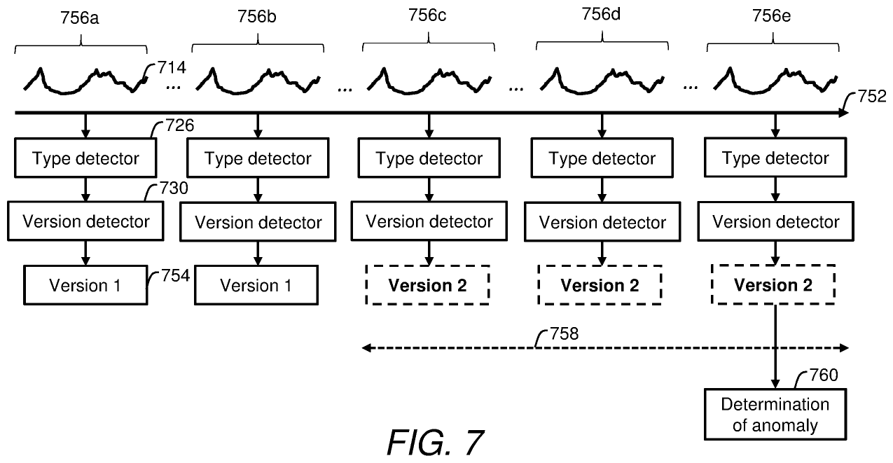

FIG. 2 is a schematic diagram of a system 200 including a device identification system 202 for identifying an active device at a premises. An active device is for example a device that is consuming electrical power and is therefore detectable from its power consumption. For example, an electric kettle which is off, and which therefore does not consume electrical power, may be considered inactive. However, if the electric kettle is subsequently turned on, the electric kettle may be considered active. The device identification system 202 may hence be used to identify a device that is in use at a particular time within the premises. Identifying active devices, e.g. electrical devices, at the premises can be used for various purposes. For example, malfunctioning devices can in some cases be identified, allowing suitable mitigating action to be taken, as discussed further with reference to FIG. 7. Moreover, by identifying the presence of a particular active device at the premises, appropriate action (such as the deployment of software or firmware updates to protect against vulnerabilities associated with that particular device) can be performed to improve security.

The device identification system 202 of FIG. 2 can identify an active device based on power consumption data associated with a premises (such as power consumption of devices within, connected to, mounted on or otherwise associated with the premises). In this case, the power consumption data includes first and second power consumption data indicative of a first and second power consumption associated with the premises within a first and second time period, respectively, where the second time period is subsequent to the first time period. The power consumption data for a given time period may be obtained in various ways. For example, the power consumption data for a particular premises may be obtained from a smart meter. In this case, the power consumption data for example represents an aggregated power of a plurality of devices within the premises. In other cases, though, the power consumption data may be obtained from a different source or a plurality of sources, such as a plurality of smart meters or a plurality of smart plugs within the premises.

The device identification system 202 includes a device prediction component 204, which is configured to determine a predicted identity 206 of an active device at the premises within the second time period, based on the first power consumption data. In other words, prior power consumption is used by the device prediction component 204 as a predictor of current power consumption. In the example of FIG. 2, the device prediction component 204 is arranged to process a previous determination 208 of an active device at the premises within at least the first time period (which is before the time period for which the predicted identity 206 is to be obtained), to generate the predicted identity 206. In this case, the previous determination 208 was itself generated based on at least the first power consumption data.

The device identification system 202 of FIG. 2 also includes a device detection component 210, which is configured to determine, based on the second power consumption data, a detected identity 212 of the active device at the premises within the second time period. Hence, in this case, the device detection component 210 obtains the detected identity 212 based on current power consumption data 214 (which in this case represents the power consumption for the second time period).

With this approach, two attempts are made at identifying the active device at the premises within the second time period. One of the attempts uses the device prediction component 204 to obtain the predicted identity 206, and the other attempt uses the device detection component 210 to obtain the detected identity 212. The predicted identity 206 may be obtained while obtaining the detected identity 212 (i.e., in parallel), to reduce the overall time taken to identify the active device. In other cases, though, the predicted identity 206 may be obtained before or after the detected identity 212 is obtained.

In the example of FIG. 2, the device identification system 202 includes a decision component 216 to determine a determined identity 218 of the active device at the premises within the second time period, based on at least one of the predicted identity 206 and the detected identity 212. The determined identity 218 for example corresponds to the identity output by the device identification system 202. This approach improves the performance of the device identification system 202, for example by increasing the robustness of the determined identity 218. For example, if both the device prediction component 204 and the device detection component 210 identify the same identity for the active device, the decision component 216 can determine the determined identity 218 with greater confidence than otherwise. Conversely, if one of the device prediction component 204 and the device detection component 210 is unable to ascertain the identity of the active device (or unable to ascertain the identity with sufficient confidence), the identity obtained from the other one of the device prediction component 204 and the device detection component 210 can be taken as the determined identity 218 by the decision component 216.

The decision component 216 in the example of FIG. 2 is configured to receive a first confidence score 220 associated with the predicted identity 206 and a second confidence score 222 associated with the detected identity 212. The first and second confidence scores 220, 222 indicate a confidence in the predicted and detected identities 206, 212, respectively, which for example indicate how reliable the device prediction and detection components 204, 210 consider the predicted and detected identities 206, 212 to be. For example, a high first confidence score 220 may indicate that the device prediction component 204 has determined that the predicted identity 206 is reliable and has a high likelihood of being the correct identity of the active device. If, however, the first confidence score 220 is lower, this may indicate that the predicted identity 206 is less reliable, and that the device prediction component 204 has lower confidence that the predicted identity 206 is the correct identity of the active device. The first confidence score 220 may be generated by the device prediction component 204 and the second confidence score 222 may be generated by the device detection component 210. The first and second confidence scores 220, 222 may correspond to respective errors involved in predicting and detecting the identity of the active device, respectively. Such errors may for example include statistical uncertainties and/or uncertainties associated with the method(s) used by the device prediction and detection components 204, 210. In some cases, the first and second confidence scores 216, 222 may be predetermined. In such cases, the first and/or second confidence scores 220, 222 may be based on past successes of the device prediction and detection components 204, 210 in correctly predicting and detecting the identity of an active device associated with particular characteristics (e.g. power consumption characteristics) which are similar to characteristics of the second time period. For example, the device detection component 210 may have had a relatively high success rate in correctly detecting the identity of an active device based on power consumption with certain features (e.g. within a particular magnitude range). The second confidence score 222 may hence be relatively high for a detected identity 212 generated by the device detection component 210 based on a second power consumption with similar features.

In FIG. 2, the decision component 216 may perform a comparison 224 between the first and second confidence scores 220, 222 in order to determine the determined identity 218. The comparison 224 may be omitted if the predicted identity 206 is the same as the detected identity 212, to reduce the processing performed. If the predicted identity 206 differs from the detected identity 212, the comparison 224 may be performed to identify which of the predicted identity 206 or the detected identity 212 is associated with the higher confidence score (e.g. by determining whether the first confidence score 220 is higher or lower than the second confidence score 222).

In some cases, the identity associated with the higher confidence score is used as the determined identity 218. For example, if the second confidence score 222 is higher than the first confidence score 220, this indicates that the device detection component 210 has higher confidence in the detected identity 212 than the device prediction component 204 has in the predicted identity 206. In this case, the predicted identity 206 is neglected and the detected identity 212 is taken as the determined entity 218.

If the first and second confidence scores 220, 222 are the same, the determined identity 218 may be taken from the more reliable one of the device prediction component 204 and the device detection component 210. A determination as to which of the device prediction or device detection components 204, 210 is more reliable may be performed prior to deployment of the device identification system 202 or updated during use of the device identification system 202 (e.g. based on a performance of the device prediction or device detection components 204, 210). In other cases, one of the device prediction component 204 and the device detection component 210 may be preselected as the default component to use if the first and second confidence scores 220, 222 are the same.

In some cases, the device detection component 210 may be more reliable than the device prediction component 204, e.g. if the behavior of a person within the premises changes over time or if a new person occupies the premises and behaves differently than a previous occupant. In these cases, prior activity within the premises may not be a good predictor for future activity, reducing the reliability of the device prediction component 204. To account for this, the detected identity 212 is taken as the determined identity 218 if the first and second confidence scores 220, 222 are the same in some cases. In these cases, the relatively lower reliability of the device prediction component 204 may be further taken into account by taking the predicted identity 206 as the determined identity 218 if the first confidence score 220 exceeds the second confidence score 222 by an amount which meets or exceeds a threshold amount. In other words, for the predicted identity 206 to be taken as the determined identity 218, the confidence in the predicted identity 206 must be higher by a certain amount than the confidence in the detected identity 212, due to the inherently lower reliability of predicting device identity based on past activity.

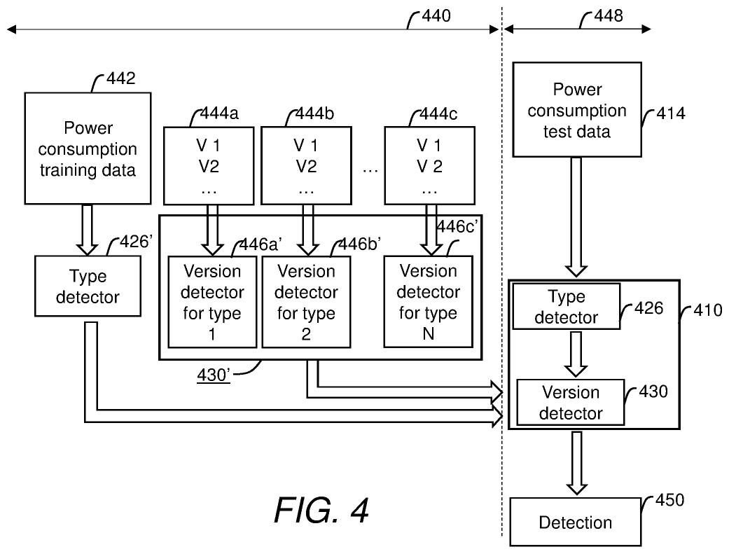

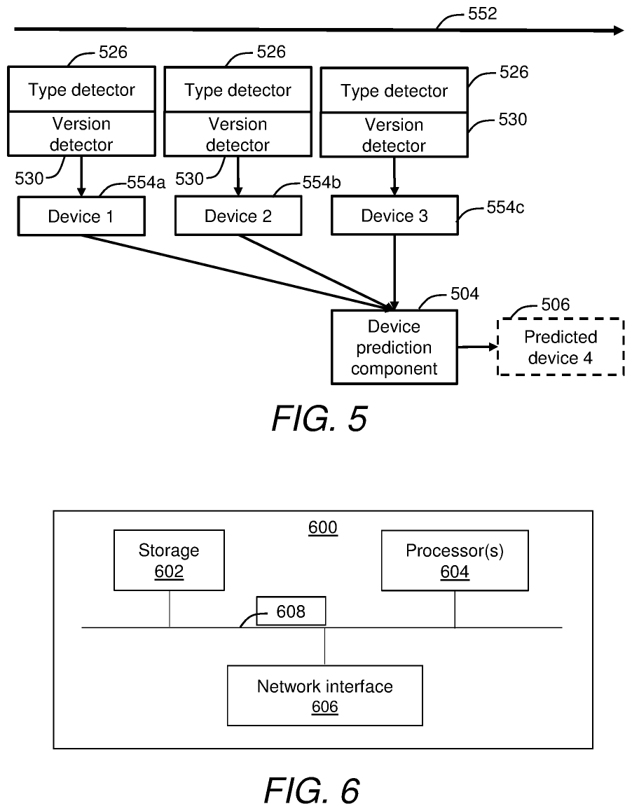

The determined identity 218 may be used to update the device identification system 202, indicated by the solid arrows from the determined identity 218 to the device prediction component 204 and to the device detection component 210. For example, if the decision component 216 determines that the determined identity 218 corresponds to the detected identity 212 and if the device prediction component 204 includes a first machine learning (ML) system, the first ML system may be retrained based on the determined identity 218 (as discussed further with reference to FIG. 5). This allows the device prediction component 204 to be updated, for example to take into account new behavior within the premises, which previously the device prediction component 204 was unable to accurately predict. Conversely, if the decision component 216 determines that the determined identity 218 corresponds to the predicted identity 206 and if the device detection component 210 includes a second machine learning (ML) system, the second ML system may be retrained based on the determined identity 218 (as discussed further with reference to FIG. 4).

At least one of the predicted identity 206, detected identity 212 or determined identity 218 for the second time period may be used as a previous determination 208 for a time period subsequent to the second time period. A similar approach may have been used to obtain the previous determination 208 used to obtain the determined identity 218 for the second time period. This is indicated schematically in FIG. 2 by the dashed arrows from the predicted identity 206, detected identity 212 and determined identity 218 to the previous determination 208. For example, at least one of the device prediction component 204, the device detection component 210 or the decision component 218 are further configured to process the first power consumption data to generate device usage data representing an identity of at least one active device at the premises for each of at least one time period prior to the time period for which the determined identity 218 is to be obtained (e.g. at least one portion of the first time period, where the determined identity 218 is to be obtained for the second time period). In one case, the detected identity 212 obtained by the device detection component 210 for each of at least one time period prior to the second time period (e.g. each of at least one portion of the first time period) is used as the previous determination 208. In such cases, the device usage data may represent the previous determination 208. In these cases, the device prediction component processes the device usage data to determine the predicted identity 206 for the second time period.

Hence, in some cases, the first power consumption data (corresponding to the power consumption associated with the first time period) is processed to generate device usage data representing an identity of at least one active device at the premises for each of at least one portion of the first time period, respectively. For example, the first power consumption data may be processed by the device detection component 210 to obtain a detected identity for the first time period, which detected identity may then be processed by the device prediction component 204 to predict the predicted identity for the second time period. This improves efficiency, by allowing the results of previous processing to be re-used for subsequent identity determination. However, it is to be appreciated that, in some cases, the first power consumption data may be processed by a different component than the device prediction component 204, the device detection component 210 or the decision component 218 to obtain device usage data, e.g. to provide the device usage data in a suitable form for processing by the device prediction component 204. Furthermore, in some cases, the device prediction component 204 may be configured to process the first power consumption data itself to obtain the predicted identity 206, rather than processing the device usage data.

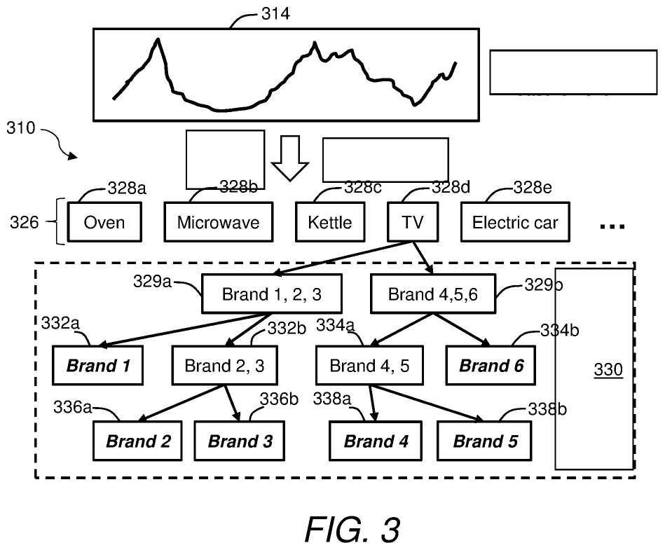

FIG. 3 is a schematic diagram of a device detection component 310 according to examples. The device detection component 310 of FIG. 3 may be used as the device detection component 210 of FIG. 2, for example. The device detection component 310 of FIG. 3 is configured to process power consumption data 314 (e.g. for a second time period as explained with reference to FIG. 2) obtain a detected identity of an active device which is active at a premises within the second time period, where the detected identity indicates a version of a particular type of the active device. The type of the active device for example indicates a class of the active device, such as which category of appliance the device corresponds to. In contrast, the version for example indicates a particular model of a given type of appliance, where the model may be a hardware, software and/or firmware model and/or may indicate the brand of the given type of appliance. In general, the power consumption of a particular device depends on various factors, such as processing performed by the device (and the type of processor used to perform the processing), the size, the functionality, the technology and so forth. The dependence of the power consumption on these various factors is exploited by the device detection component 310 in the example of FIG. 3 to distinguish between different versions of devices of the same type, which will typically have different power consumption features from each other. For example, an organic light-emitting diode (OLED) television (TV) typically has lower power consumption for the same screen size and brightness as a liquid crystal display (LCD) TV. However, a TV with a larger screen size and/or higher brightness typically has a higher power consumption. In general, different versions (e.g. different models) of a device, such as different TVs, provided by the same or different manufacturers will have different power consumption features.

In some cases, as explained above, the power consumption data 314 is aggregated power consumption data that represents the power consumption of a plurality of active devices associated with the premises. For example, the power consumption data 314 may be obtained from a smart meter of the premises. In such cases, device-specific power consumption data indicative of a power consumption of the active device at the premises within a particular time period may be disaggregated from the power consumption data 314. The device-specific power consumption data may then be processed by the device detection component 310 rather than processing the aggregated power consumption data. This can improve the accuracy with which the device detection component 310 is able to identify the active device. Various techniques may be used for the disaggregation, such as existing NILM techniques that would be well-known to the skilled person. For example, on-off events or other characteristic features may be identified from the power consumption data 314, and used to extract the device-specific power consumption data from the (aggregated) power consumption data 314.

In the example of FIG. 3, the device detection component 310 includes a type detection component 326, which is configured to process the power consumption data 314 to determine the particular type of the active device, e.g. whether it is an oven 328a, a microwave 328b, a kettle 328c, a television 328d, an electric car 328e and so on. The type detection component 326 may for example use an existing ALM technique, such as a NILM technique. Suitable NILM techniques are described in “Non-Intrusive Load Monitoring Approaches for Disaggregated Energy Sensing: A Survey” by A. Zoha et al., published in Sensors vol. 12, no. 12, pp. 16838-16866, 2012, the contents of which are hereby incorporated by reference. In some cases, an NILM technique may be used to both disaggregate aggregated power consumption data and to identify the particular type of the active device.

After determining the particular type of the active device, the device detection component 310 is configured to process the power consumption data using a version detection component 330 configured to detect the version of the particular type of active device. In this example, the version detection component 330 comprises a hierarchical support vector machine (HSVM). The inventors have identified that an HSVM is particularly effective at identifying the version of an active device from power consumption data. Various features, such as high and/or low frequency features can be considered by the HSVM depending on the availability of data representing these features. For example, the power consumption data may represent a plurality of different power consumption features, which may be high and/or low frequency features. For example, the power consumption data may represent steady state power consumption features that can be obtained at lower frequencies and/or transient power consumption features of a higher frequency.

An HSVM includes a hierarchy of support vector machines (SVM). Each SVM can be used to identify an optimal hyperplane to separate data into two categories (i.e. binary classification). By including a hierarchy of SVMs, the HSVM can be used to separate data into a plurality of different categories (although each individual SVM continues to classify data into one of two categories, respectively). Hence, an HSVM can be used to iteratively distinguish between various versions of devices of the same type, e.g. belonging to the same class, based on power consumption. For example, an HSVM can be used to distinguish between two different brands or models of toaster rather than merely identifying that an active device is a toaster. An HSVM operates by iteratively classifying an active device associated with the power consumption data into one of two classes until a class corresponding to a single version is identified.

Classification of an active device using an HSVM is shown schematically in FIG. 3, in which the version detection component 330 is configured to distinguish between different brands of TV, with each brand corresponding to a different respective version of TV. In this case, a first SVM associated with a first level in a hierarchy is configured to process the power consumption data to identify whether the active device is a first, second or third brand 329a or a fourth, fifth or sixth brand 329b. Second and third SVMs are associated with a second level in the hierarchy. The second SVM is configured to process the power consumption data to identify whether the active device is a first brand 332a or a second or third brand 332b. The third SVM is configured to process the power consumption data to identify whether the active device is a fourth or fifth brand 334a or a sixth brand 334b. Fourth and fifth SVMs are associated with a third level in the hierarchy. The fourth SVM is configured to process the power consumption data to identify whether the active device is a second brand 336a or a third brand 336b. The fifth SVM is configured to process the power consumption data to identify whether the active device is a fourth brand 338a or a fifth brand 338b. The classification performed by the version detection component 330 ceases when the active device has been detected as the first brand 332a, the second brand 336a, the third brand 336b, the fourth brand 338a, the fifth brand 338b or the sixth brand 334b.

In this case, the HSVM is configured to process device-specific power consumption data (which may be obtained by disaggregating aggregated power consumption data 314, or by obtaining power consumption data specific to the particular active device, such as from a smart plug of the active device). Processing device-specific power consumption data improves the performance of the device detection component 310 as it for example allows the device detection component 310 to be configured more specifically to distinguish between particular versions of a given type of active device, rather than having to identify both the version and the type of the active device. This can for example simplify training of the device detection component 310 if the device detection component 310 is implemented as, or otherwise comprises, a machine learning system. However, it is to be appreciated that, in other examples, the functionality of type and version detection may be performed together, e.g. by a machine learning system trained to process aggregated power consumption data to identify both the version and type of the active device.

As the device detection component 310 may be used to determine the version of the active device, the determined identity of the active device (which may be determined based on at least one of the detected identity detected using the device detection component 310 or the predicted identity predicted using a device prediction component 204) may also indicate the version of the active device. As explained above, a detected identity detected using the device detection component 310 for at least one time period (e.g. at least one portion of a first time period) prior to a time period for which the identity of the active device is to be determined (e.g. a second time period) may be used to obtain the predicted identity (e.g. for the second time period). For example, device usage data may represent, for each active device of at least one active device active within the at least one time period, a version of the particular type of the respective active device. Hence, the predicted identity may also indicate the version of the active device.

Identifying the version of the active device improves device identification compared to merely identifying the type of the active device. For example, a more tailored service can be provided to the active device than otherwise, e.g. by providing a service to the active device that is appropriate for the capabilities of the version of the active device. This can reduce network traffic (e.g. where the service is provided by a network such as the telecommunications network 100 of FIG. 1) by providing a particular service that is supported by the version of the active device, without providing a service that is unsupported by the version of the active device. For example, it may be determined that the active device is a smart TV capable of supporting content of a particular format, e.g. 4K content. For example, by determining the version of the TV, it may be identified that the TV has a resolution corresponding to a horizontal pixel count of approximately 4,000, and for example conforms with a particular standard such as a Digital Cinema System Specification standard set by the Digital Cinema Initiatives (DCI) organization or an Ultra High Definition TV (UHDTV) standard set by the Society of Motion Picture and Television Engineers or the International Telecommunication Union, Radiocommunication Sector (ITU-R). If it is determined that the active device is capable of supporting particular content, that content can be provided to the TV without providing other content which is either unsupported or unnecessary. For example, 4K content can be provided to a 4K-capable smart TV without providing lower resolution content. Conversely, if it is determined that the smart TV is incapable of supporting 4K content, the lower resolution content can be provided without providing the 4K content. This reduces the bandwidth for transmitting content to the device, while maintaining the quality of the service provided.

The appropriate service to provide to a given active device may include the deployment of a security update. For example, if it is identified, using a device identification system as described herein, that a particular version of a particular type of device is present at a premises, a determination can be made as to whether to deploy a security update. If the particular version has a known security vulnerability for which there is a security update, the security update can be deployed or a user of the device can be notified about the availability of the security update, e.g. via a client device of the user which is associated with the active device. This can improve the security of the active device.

To facilitate the provision of an appropriate service to a particular active device, such as content of an appropriate format or deployment of a security update, an indication of the determined identity (e.g. determined as explained with reference to FIG. 2), may be sent to a gateway device of a network associated with a premises, such as the gateway device 104 of FIG. 1, for use in determining a service to provide to the premises. For example, the gateway device 104 may send the indication to a further component for determining the appropriate service to provide, such as a security system for identifying whether to provide a security update or a computer system associated with a content provider for identifying whether to provide content of a particular format (e.g. 4K content), or may itself determine a service to be provided to the active device.

In the example of FIG. 3, the device detection component 310 comprises a HSVM, which is an example of a ML system. FIG. 4 is a schematic diagram of training of a device detection component 410, which may be similar to or the same as the device detection component 310 of FIG. 3. Like the device detection component 310 of FIG. 3, the device detection component 410 of FIG. 1 includes a type detection component 426 and a version detection component 430.

During a training time period 440, power consumption training data 442 is provided to the type detection component 426′. As used herein, a prime in a reference numeral indicates that the component is undergoing training; a corresponding component after training is indicated with the same reference numeral but without a prime. Any suitable training approach may be used, as the skilled person will appreciate. The power consumption training data 442 may be similar to the power consumption data 314 of FIG. 3, but may be annotated data, e.g. if the device detection component 410 is to be trained using supervised learning. In other words, the power consumption training data 442 may include labelled input-output pairs as training examples, each indicating the correct type to be identified from particular power consumption features associated with a given device.

The version detection component 430′ may also be trained during the training time period 440, but using different training data than the power consumption training data 442 used in training the type detection component 426′. The training data used to train the version detection component 430′ in the example of FIG. 4 includes a plurality of sets of training data (three of which are shown in FIG. 4 and labelled with the reference numerals 444a-444c), each associated with a different type of device. For example, a first set of training data 444a may be used to train a first version detection element 446a′ for detecting different respective versions of a first type of device. The first set of training data 44a for example includes device-specific power consumption for different versions of the first type of device, which may be annotated as explained above for the power consumption training data 442. In this way, the version detection component 430′ may be trained to include a plurality of version detection elements, each corresponding to a different respective type of device, and configured to detect different versions of the respective type of device. For example, the first version detection element 446a′ may be trained to detect different versions of smart TVs, a second version detection element 446b′ may be trained to detect different versions of kettles and a third version detection element 446c′ may be trained to detect different versions of microwaves.

During a test time period 448, the trained device detection component 410 is configured to process power consumption test data 414, which is for example the same as the power consumption data 314 of FIG. 3, to output a detection 450 of a detected version of a particular type of active device, as explained further with reference to FIGS. 2 and 3. The version detection component 430 of the device detection component 410 in this case includes trained versions of each of the plurality of version detection elements 446a′-446c′. It is to be appreciated that, although not shown in FIG. 3, the version detection component 330 of FIG. 3 may similarly have a plurality of version detection elements to detect different versions of different respective types of device (although the version detection component 330 shown in FIG. 3 includes solely the components of a version detection element to detect different versions of a single type of device—a TV).

As explained with reference to FIG. 2, if the predicted identity 206 is taken as the determined identity 218 by the decision component 216 (e.g. due to being associated with a greater confidence than the detected identity 212), the device detection component 410 may be retrained based on the determined identity 218. For example, the current power consumption data 214 (which the device detection component 210 classified differently, and e.g. with lower confidence, than the device prediction component 204) may be used as power consumption training data 442 for retraining the type detection component and/or a set of training data 444a-444c for training a version detection element of the version detection component.

FIG. 5 is a schematic diagram of a device prediction component 504 according to examples. The device prediction component 504 of FIG. 5 may for example be used as the device prediction component 204 of FIG. 2. The device prediction component 504 for example includes a ML model of the typical pattern of power consumption associated with the premises. The device prediction component 504 therefore exploits the fact that people tend to exhibit a repetitive patterns of behavior. For example, an occupier of the premises may typically turn on certain devices at particular times of the day or on particular days. The device prediction component 504 is configured to predict the most-likely device to be active in a given time period given a prior history of device usage (e.g. of other devices).

In the example of FIG. 5, the device prediction component 504 is configured to process device usage data representing an identity of an active device at a premises for each of a plurality of time periods to predict an identity of an active device at the premises in a subsequent time period, subsequent to the plurality of time periods. Time is indicated with an axis 552 in FIG. 5. In other words, rather than using raw power consumption as an input to the device prediction component 504, the device prediction component 504 instead receives a sequence of active devices (e.g. a sequence of device activations over time). This for example improves the accuracy of the prediction obtained by the device prediction component 504 as the device prediction component 504 configured in this way for example more fully captures expected patterns of behavior within the premises, providing for more accurate predictions.

In FIG. 5, a type detection component 526 and a version detection component 530, which may be similar to the type detection components 326, 426 and the version detection components 330, 430 of FIGS. 3 and 4 respectively, are used to obtain a detected identity of an active device 554a-554c for each of a plurality of time periods, based on processing of power consumption data indicative of a power consumption associated with the premises for the respective time period. In a first time period, the active device is identified as being a first device 554a, in a second time period, the active device is identified as being a second device 554b and in a third time period, the active device is identified as being a third device 554c. The first, second and third devices 554a-554c may be different respective types of device or different versions of the same type of device. The detected identity obtained by the type detection component 526 and the version detection component 530 for at least one time period may correspond to an identity of a device that has been activated in the at least one time period, e.g. a device which has changed state such as from an off state to an on state within a respective time period. Such a device may be considered an active device in that it is active for at least part of the time period. In other cases, though, the detected identity for at least one of the time periods may be a device which has remained active, i.e. for which the state of the device is unchanged. Device usage data may be used to represent the identity of the first to third devices 554a-554c, and may further indicate in which time period the first to third devices 554a-554c were active, so as to represent a sequence of active devices within the premises.

The device prediction component 504 processes the device usage data to predict a predicted identity 506 of an active device, which is active in a fourth time period after the first to third time periods. For example, the predicted identity 506 may be the same as the identity of the third device 554c, if the device prediction component predicts that the device is to remain active from the third time period and into the fourth time period. In other cases, though, the predicted identity 506 may represent the identity of a different active device, e.g. where the device prediction component 504 is configured to predict the most likely device to be activated subsequently rather than a device which is most likely to be or remain active subsequently.

The device prediction component 504 in some cases includes a long short-term memory (LSTM) neural network. An LSTM is particularly suitable for obtaining the predicted identity 506 of the active device within a given time period, based on activity within previous time periods, as an LSTM has feedback connections to account for sequences of activity. In other cases, though, a different approach may be used, such as a different ML architecture.

As explained with reference to FIG. 2, if the detected identity 212 obtained by a device detection component 210 is taken as the determined identity 218 by the decision component 216 for a given time period (e.g. due to being associated with a greater confidence than the detected identity 212), the device prediction component 504 may be retrained based on the determined identity 218. For example, if the device prediction component 504 includes a ML system such as an LSTM neural network, the ML system may be retrained based on updated device usage data indicative that a device of the determined identity 218 was active at the premises within a given time period. In this way, the performance of the device prediction component 504 can be improved over time, to account for new power consumption behavior at the premises.

FIG. 6 is a schematic diagram of internal components of a computer system 600 that may be used in any of the methods described herein. For example, the computer system 600 may be used to implement a device identification system, a device prediction component and/or a device detection component. The computer system 600 may include additional components not shown in FIG. 6; only those most relevant to the present disclosure are shown. The computer system 600 in FIG. 6 is implemented as a single computer device but in other cases may be implemented as a distributed system.

The computer system 600 includes storage 602 for storing computer-program instructions. The storage 602 may be or include volatile or non-volatile memory, read-only memory (ROM), or random access memory (RAM). The storage 602 may be referred to as memory, which is to be understood to refer to a single memory or multiple memories operably connected to one another. The storage 602 may be or include a non-transitory computer-readable storage medium. A non-transitory computer-readable storage medium includes, but is not limited to, volatile memory, non-volatile memory, magnetic and optical storage devices such as disk drives, magnetic tape, compact discs (CDs), digital versatile discs (DVDs), or other media that are capable of storing code and/or data. The storage 602 is for example arranged to store power consumption data received from a premises, e.g. from at least one smart meter or smart plug.

The computer system 600 also includes at least one processor 604 which may be used to implement the methods described herein for device identification. The at least one processor 604 may be or comprise processor circuitry. The at least one processor 604 is arranged to execute program instructions and process data. The at least one processor 604 may include a plurality of processing units operably connected to one another, including but not limited to a central processing unit (CPU) and/or a graphics processing unit (GPU). In this case, the at least one processor 604 is arrange to process computer-program instructions received from the storage 602 to instruct the computer system 600 to perform a device identification method according to examples herein.

The computer system 600 further includes a network interface 606 for connecting to at least one network, such as the local network 102 and the Internet 106 as shown in FIG. 1. The components of the computer system 600 are communicably coupled via a suitable bus 608.

As explained above, in examples in accordance with FIG. 2, first power consumption data indicative of a first power consumption associated with a premises within a first time period may be processed to obtain device usage data representing an identity of at least one active device for each of at least one portion of the first time period, respectively. In the above-described examples, the device usage data is processed to determine the predicted identity of an active device within a second time period subsequent to the first time period. However, in other examples, the device usage data may additionally or alternatively be used for a different purpose, as shown in FIG. 7.

FIG. 7 is a schematic diagram illustrating determination of anomalies using the methods herein. FIG. 7 illustrates a plurality of time periods 756a-756e (collectively referred to with the reference numeral 756), with respect to a time axis 752. At each time period 756, power consumption data 714 is processed by a type detection component 726 and a version detection component 730 (which are labelled for the first time period, and which may be similar to or the same as the type detection component 526 and the version detection component 530 of FIG. 5, respectively), to obtain a detected identity 754 of an active device (labelled for the first time period) for a particular time period 756. The detected identities 754 for the time periods 756 for example correspond to device usage data, as discussed further above.

In the example of FIG. 7, it is determined, based on the device usage data, whether the device usage data represents different versions of the same type of active device within different respective portion of the first time period. In FIG. 7, a particular type of device is identified as being of a first version in the first two time periods 756a, 756b. However, in the third to fifth time periods, the type detection component 726 and the version detection component 730 (which for example correspond to a device detection component) the active device is detected as being of a second version of the particular type of device.

The appearance of a new detected version of the same type of device within a premises is considered potentially anomalous. For example, the new detected version may have been detected because a new version of a particular type of device has genuinely been introduced into the premises. However, the new detected version may instead indicate that the current version of the device has malfunctioned, which may cause a change to the power consumption of the device. In some cases, a change in a detected version of a particular device may indicate that the device has suffered a security breach (e.g. a hack), which may increase the power consumption of the device.

To improve robustness, the appearance of a new detected version of the same type of device may be identified as being anomalous if certain condition(s) are met, e.g. if the presence of the new version is detected consistently across a plurality of time periods. In the present case, the second version is identified as being present within a time window 758 with a length which equals or exceeds a threshold length. In this case, as the detection of the second version has persisted over time, it is determined 760 that there is an anomaly in the premises, e.g. that the particular device which was previously detected in the first two time periods 756a, 756b is behaving anomalously. A suitable notification may be sent to a user associated with the premises, e.g. via a client device, and/or mitigating action may be taken to reduce the risk of further security breaches, such as sending instructions to the anomalous device to restrict functionality of the device or deploying a security update to the anomalous device. The approach of FIG. 7 may be performed repeatedly over time, to monitor the presence of devices associated with the premises and identify anomalies.

A similar approach may be taken to detect rogue devices connected to a particular network, such as the local network 102 of FIG. 1. For example, it may be determined, based on at least one of the predicted identity, the detected identity or the determined identity, whether the active device corresponds to a previously-unseen device within the premises. For example, the at least one of the predicted identity, the detected identity or the determined identity may be stored in suitable storage, such as the storage 602 of FIG. 6, and newly-obtained predicted, detected and/or determined identities may be compared against previously-obtained predicted, detected and/or determined identities to identify whether a device was previously observed as being active within the premises. In other cases, a previously-unseen device may be detected based on the power consumption itself, e.g. if at least one feature of the power consumption indicates a deviation from normal behavior (such as a large spike in power consumption). In yet further cases, a previously-unseen device may be detected based on the confidence score associated with the predicted or detected identities. For example, if both of the confidence scores fail to satisfy a particular confidence criterion (indicating that the device identification system has low confidence in the accuracy of the determined identity), the device identified for a given time period may be considered to be a previously-unseen device. As explained with reference to FIG. 7, if a previously-unseen device is detected, this may indicate an anomaly such as a malfunctioning device or a device that has suffered a security breach, which can be addressed appropriately as explained with reference to FIG. 7.

### Alternatives and Modifications

In the example of FIG. 1, the server 108 includes the device identification system. In other cases, though, the device identification system may be arranged on a different component or system (which may be a distributed system). For example, the local network 102 may include a computer system configured to implement the device identification system or the gateway device 104 of the local network 102 may be configured to implement the device identification system (alone or in conjunction with a further computer system, such as the server 108).

In examples in which at least one of the device prediction component or the device detection component includes a ML system, the ML system may produce a confidence score associated with a particular output, such as the first or second confidence scores discussed above. As the skilled person will appreciate, there are various methods for determining the confidence score associated with a particular output of an ML system, which depend on the ML system used. For example, for an SVM (a hierarchy of which may be used to form an HSVM such as that of the version detection component 330 of FIG. 3), the probability that a given active device is of a particular category may be determined using Platt scaling, and may be taken as a confidence score. For an LSTM (which may be used as or as part of a device prediction component 504), dropout can be used to obtain a confidence interval for a predicted device identity, from which a confidence score associated with the predicted device identity can be obtained.

The device detection component 310 of FIG. 3 is configured to identify a version of an active device. However, in other cases, a device detection component (such as the device detection component 210 of FIG. 2) may not identify a version of an active device and may instead merely determine a particular type of the active device (e.g. that the active device is a smart TV, without identifying the particular model of smart TV). In such cases, the device detection component may be the same as or similar to the type detection component 326 of FIG. 3.

Although examples above relate to a device identification system including a device prediction component and a device detection component, it is to be appreciated that a device prediction component or a device detection component as described in examples herein may be used independently in further examples. For example, a device prediction component such as that of FIG. 3 may be used as described with reference to FIG. 7 to identify anomalous devices. In other cases, a device prediction component such as that of FIG. 5 may be used to predict activity within a network (e.g. that certain devices are going to be active at a given time). Bandwidth may then be allocated, e.g. to different respective devices, based on the prediction.

The determined identity obtained in examples herein may be used for various purposes such as the purposes described above, and/or other purposes. For example, the determined identity for respective time periods can be used to build a profile of power consumption for a particular premises, which can be used for various purposes.

Each feature disclosed herein, and (where appropriate) as part of the claims and drawings may be provided independently or in any appropriate combination.

Any reference numerals appearing in the claims are for illustration only and shall not limit the scope of the claims.

In general, it is noted herein that while the above describes examples, there are several variations and modifications which may be made to the described examples without departing from the scope of the appended claims. One skilled in the art will recognize modifications to the described examples.

1. A device identification method comprising:
determining, based on first power consumption data indicative of a first power consumption associated with a premises within a first time period, a predicted identity of an active device at the premises within a second time period subsequent to the first time period;
determining, based on second power consumption data indicative of a second power consumption associated with the premises within the second time period, a detected identity of the active device at the premises within the second time period; and
determining, based on at least one of the predicted identity or the detected identity, a determined identity of the active device at the premises within the second time period.

2. The method of claim 1, wherein at least one of the predicted identity, the detected identity, or the determined identity indicates a version of a particular type of the active device.

3. The method of claim 2, wherein determining the detected identity comprises:
detecting, based on the second power consumption data, the particular type of the active device; and
after detecting the particular type of the active device, detecting, based on the second power consumption data, the version of the particular type of the active device.

4. The method of claim 3, wherein detecting the version of the particular type of the active device comprises processing the second power consumption data using a hierarchical support vector machine.

5. The method of claim 1, further comprising processing the first power consumption data to generate device usage data representing an identity of at least one active device at the premises for each of at least one portion of the first time period, respectively.

6. The method of claim 5, wherein determining the predicted identity comprises processing the device usage data to determine the predicted identity.

7. The method of claim 6, wherein processing the device usage data comprises processing the device usage data using a long short-term memory (LSTM) neural network.

8. The method of claim 5, wherein the device usage data represents, for each respective active device of the at least one active device, a version of a particular type of the respective active device.

9. The method of claim 8, further comprising determining, based on the device usage data, whether the device usage data represents different versions of a same type of active device within different respective portions of the first time period.

10. The method of claim 1, further, comprising disaggregating, from the second power consumption data, device-specific power consumption data indicative of a power consumption of the active device at the premises within the second time period,
wherein determining the detected identity comprises processing the device-specific power consumption data to determine the detected identity.

11. The method of claim 1, wherein determining the determined identity of the active device comprises determining the determined identity of the active device based on at least one of a first confidence score associated with the predicted identity or a second confidence score associated with the detected identity.

12. The method of claim 11, wherein determining the determined identity of the active device comprises determining that the determined identity of the active device corresponds to the predicted identity based on the first confidence score exceeding the second confidence score by an amount which meets or exceeds a threshold amount.

13. The method of claim 1, wherein determining the predicted identity comprises determining the predicted identity using a machine learning (ML) system, determining the determined identity of the active device comprises determining that the determined identity of the active device corresponds to the detected identity, and the method further comprises retraining the ML system based on updated device usage data indicative that a device of the determined identity was active at the premises within the second time period.

14. The method of claim 1, further comprising sending an indication of the determined identity to a gateway device of a network associated with the premises, for use in determining a service to provide to the premises.

15. The method of claim 1, further comprising determining, based on at least one of the first power consumption data, the second power consumption data, the predicted identity, the detected identity or the determined identity, whether the active device corresponds to a previously-unseen device within the premises.

16. A non-transitory computer-readable storage medium comprising instructions which, when executed by a computer, cause the computer to carry out the method of claim 1.

17. A device identification system comprising:
a device prediction component configured to determine, based on first power consumption data indicative of a first power consumption associated with a premises within a first time period, a predicted identity of an active device at the premises within a second time period subsequent to the first time period;
a device detection component configured to determine, based on second power consumption data indicative of a second power consumption associated with the premises within the second time period, a detected identity of the active device at the premises within the second time period; and
a decision component configured to determine, based on at least one of the predicted identity or the detected identity, a determined identity of the active device at the premises within the second time period.

18. The device identification system of claim 17, wherein at least one of the predicted identity, the detected identity, or the determined identity indicates a version of a particular type of the active device.

19. The device identification system of claim 17, wherein at least one of the device prediction component, the device detection component or the decision component are further configured to process the first power consumption data to generate device usage data representing an identity of at least one active device at the premises for each of at least one portion of the first time period, respectively, and the device prediction component is configured to process the device usage data to determine the predicted identity.

20. The device identification system of claim 19, wherein the device usage data represents, for each respective active device of the at least one active device, a version of a particular type of the respective active device.

21. A telecommunications network comprising the device identification system of claim 17.

22. A device prediction component for use in the device identification system of claim 17, wherein the device prediction component is configured to:
process device usage data representing an identity of at least one active device at a premises for each of a plurality of time periods to predict an identity of an active device at the premises in a subsequent time period, subsequent to the plurality of time periods.

23. The device prediction component of claim 22, comprising a long short-term memory (LSTM) neural network to process the device usage data.

24. The device prediction component of claim 22, wherein the device usage data represents, for each respective active device of the at least one active device, a version of a particular type of the respective active device.

25. The device prediction component of claim 22, wherein the device usage data is based on power consumption data indicative of a power consumption associated with the premises within each of the plurality of time periods.
